(19) United States
(12) Patent Application Publication
(10) Pub. No.: US 2011/0023953 A1
(43) Pub. Date: Feb. 3, 2011

(54) Solar Cell Device

(75) Inventor: Chih-Hung WU, Longtan Shiang (TW)

Correspondence Address: Jackson Intellectual Property Group PLLC, 106 Starvale Lane, Shipman, VA, 22971, US

(73) Assignee: ATOMIC ENERGY COUNCIL-INSTITUTE OF NUCLEAR ENERGY RESEARCH, Taoyuan (TW)

(21) Appl. No.: 12/510,688

(22) Filed: Jul. 28, 2009

(51) Int. Cl. H01L 31/0224

(52) U.S. Cl. 136/256

(57) ABSTRACT

A solar cell is provided Its light absorption area is close to a heat-dissipation apparatus. Thus, an excellent dissipation efficiency is obtained. The solar cell has a strong structure, an easy fabrication method and a low cost. Thus, the present invention is fit for mass-production.

### FIELD OF THE INVENTION

The present invention relates to a solar cell; more particularly, relates to having a light absorption region close to a heat dissipation apparatus where photons are absorbed firstly ones having short wavelengths then ones having long wavelengths.

### DESCRIPTION OF THE RELATED ART

In FIG. 5, a prior art of a solar cell device uses a thick substrate 7, where a first ohmic electrode 8 is deposed on at least a part of the substrate 7; an anti-reflective layer 8 is deposed on at least a part of the substrate 7; a second ohmic electrode 10 is ad he red beneath the substrate 7; and a light absorption region 7a is located in the substrate 7.

Since a thick substrate is used to support the whole structure, its heat-dissipation efficiency is bad. If the thickness of the substrate is reduced to improve the heat-dissipation efficiency, extra thickness is required to support the structure. For example, an extra substrate is bonded on wire bonding for enhancing structure of a wafer having a thin substrate. At last, the extra-added substrate has to be removed. Hence, the fabrication process becomes complex with more time and cost required and thus is not fit for mass-production. Moreover, its heat-dissipation efficiency is bad and so the temperature may easily become high. Especially, when it is shone under condensation, the temperature may be increased to a risky level to degrade its performance and even to shorten its life time. Hence, the prior art does not fulfill all users' requests on actual use.

### SUMMARY OF THE INVENTION

The main purpose of the present invention is to have a light absorption region close to a heat dissipation apparatus where photons are absorbed firstly ones having short wavelengths then ones having long wavelengths; and to make the present invention fit for mass-production through an easy fabrication method with a low cost.

To achieve the above purpose, the present invention is a solar cell device, comprising a substrate, a first ohmic electrode, an anti-reflective layer, a second ohmic electrode and a light absorption region, where the substrate has a first surface and a second surface corresponding to the first surface; the first surface has a recessed hole comprising a bottom and a sidewall; the bottom has an area smaller than that of opening of the recessed hole; the recessed hole has a depth between 20 mircrometers (μm) and 500 μm; the first ohmic electrode is deposed on the first surface, the sidewall and at least a part of the bottom; the anti-reflective layer is deposed on the bottom except areas of the first ohmic electrode; the second ohmic electrode is deposed on the second surface; the light absorption region is located in the substrate; and the light absorption region is close to the bottom. Accordingly, a novel solar cell device is obtained.

### BRIEF DESCRIPTION OF THE DRAWINGS

The present invention will be better understood from the following detailed description of the preferred embodiment according to the present invention, taken in con junction with the accompanying drawings in which

FIG. 1 is the sectional view showing the structure of the preferred embodiment according to the present invention;

FIG. 2 is the first perspective view;

FIG. 3 is the second perspective view;

FIG. 4 is the view showing the state of use; and

FIG. 5 is the view of the prior art.

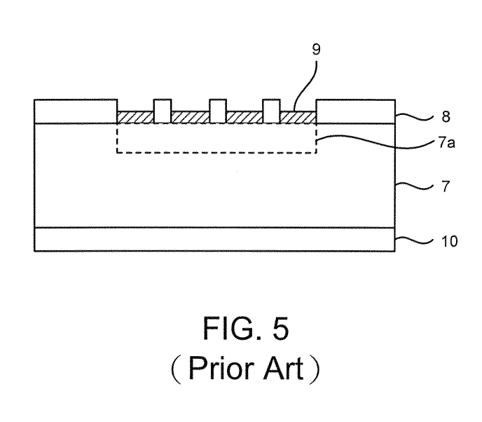

### DESCRIPTION OF THE PREFERRED EMBODIMENT

The following description of the preferred embodiment is provided to understand the features and the structures of the present invention.

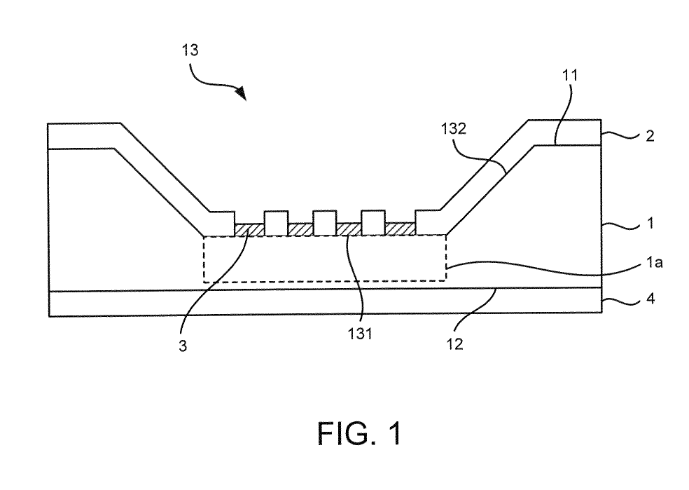

Please refer to FIG. 1, which is a sectional view showing a structure of a preferred embodiment according to the present invention. As shown in the figure, the present invention is a solar cell device, comprising a substrate 1, a first ohmic electrode 2, an anti-reflective layer 3, a second ohmic electrode 4 and a light absorption region 1a, where the light absorption region 1a is close to a heat dissipation apparatus (not shown in the figure).

The substrate 2 has a first surface 11 and a second surface 12 corresponding to the first surface 11. The first surface 11 has a recessed hole 13, where the recessed hole 13 comprises a bottom 131 and a sidewall 132; the bottom 131 has an area smaller than that of opening of the recessed hole 13; and the recessed hole 13 has a depth between 20 micrometers (μm) and 500 μm.

The first ohmic electrode 2 is deposed on the first surface 11 of the substrate 1, the sidewall 132 of the recessed hole 13, and at least a part of the bottom 131 of the recessed hole 13.

The anti-reflective layer 3 is deposed on the bottom 131 of the recessed hole 13 except areas of the first ohmic electrode 2 on the recessed hole 13, where the anti-reflective layer 3 reduces reflection loss.

The second ohmic electrode 4 is deposed on the second surface 12 of the substrate 1.

The light absorption region 1a is located in the substrate 1 and is close to the bottom 131 of the recessed hole 13. Thus, a novel solar cell device is obtained.

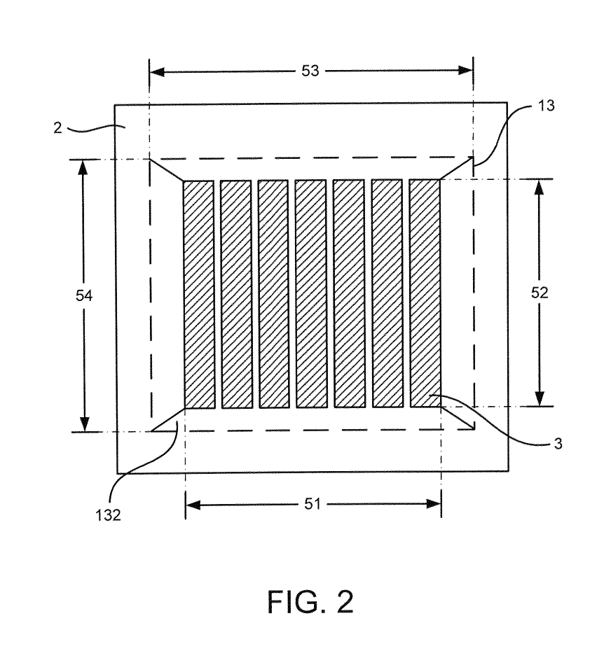

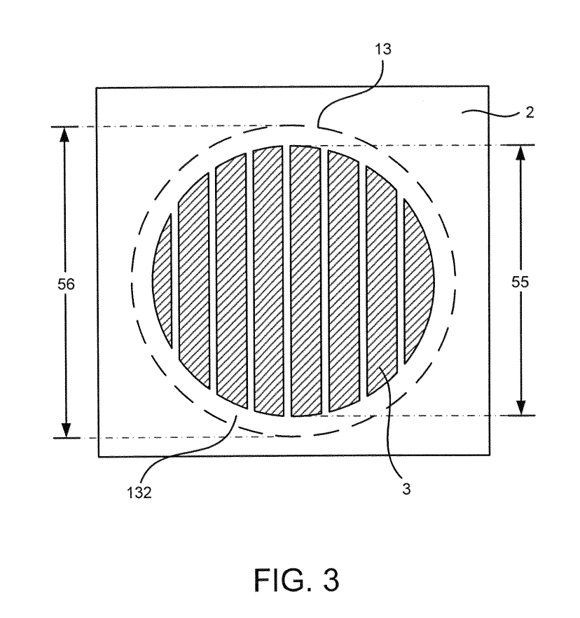

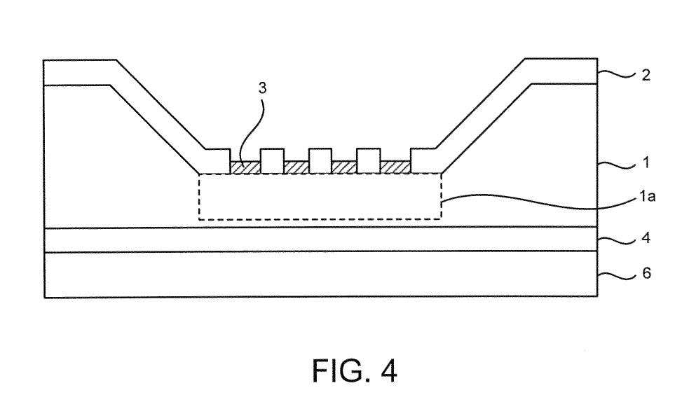

Please refer to FIG. 2 to FIG. 4, which are a first perspective view; a second perspective view; and a view showing the state of use. As shown in the figures, on using the present invention, a substrate 1 is made of silicon (Si), germanium (Ge), gallium arsenide (GaAs), aluminum oxide (Al₂O₃), gallium nitride (GaN) or indium phosphide (InP) In FIG. 3 a recessed hole 13 of the substrate 1 is a square hole, where side widths 51, 52 of a bottom 131 of the recessed hole 13 are shorter than side lengths 53, 54 of opening of the recessed hole 13 of the FIG. 4, a recessed hole 13 of the substrate 1 is a circular hole, where diameter length 55 of a bottom 131 of the recessed hole 13 is shorter than diameter length 56 of opening of the recessed hole 13.

Since the light absorption region 1a is close to a heat dissipation apparatus 6 the present invention obtains an excellent heat dissipation efficiency. Moreover the present invention has a certain thickness to support the whole structure without extra substrate bonded, where the light absorption region 1a absorbs photons firstly ones having short wavelengths then ones having long wavelengths. Thus the present invention is fit for mass-production through an easy fabrication method with a low cost.

To sum up, the present invention is a solar cell device, where a light absorption region is close to a heat dissipation apparatus and photons are absorbed firstly ones having short wavelengths then ones having long wavelengths; and the present invention is thus fit for mass-production through an easy fabrication method with a low cost.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A solar cell device, comprising
a substrate, said substrate having a first surface and a second surface said second surface being corresponding to said first surface, said first surface having a recessed hole, said recessed hole comprising a bottom and a sidewall, said bottom having an area smaller than that of opening of said recessed hole, said recessed hole having a depth between 20 micrometers (μm) and 500 μm;
a first ohmic electrode, said first ohmic electrode being deposed on said first surface of said substrate, said sidewall of said recessed hole and at least a part of said bottom of said recessed hole;
an anti-reflective layer, said anti-reflective layer being deposed on said bottom of said recessed hole except areas of said first ohmic electrode on said recessed hole;
a second ohmic electrode, said second ohmic electrode being deposed on said second surface of said substrate; and
a light absorption region, said light absorption region being located in said substrate, said light absorption region being close to said bottom of said recessed hole.

2. The device according to claim 1 wherein said recessed hole is a square hole.

3. The device according to claim 1 wherein said recessed hole is a circular hole.

4. The device according to claim 1 wherein said substrate is made of a material selected from a group consisting of silicon (Si), germanium (Ge), gallium arsenide (GaAs), aluminum oxide (Al₂O₃) gallium nitride (GaN) and indium phosphide (InP).
